(19) United States
(12) Patent Application Publication
(10) Pub. No.: US 2002/0096786 A1
(43) Pub. Date: Jul. 25, 2002

(54) Intermediate support for supporting a semiconductor module on a circuit carrier

(76) Inventor: Jozef Van Puymbroeck, Oostkamp (BE)

Correspondence Address: SCHIFF HARDIN & WAITE, 6600 SEARS TOWER, 233 S WACKER DR, CHICAGO, IL, 60606-6473, US

(21) Appl. No.: 10/016,925

(22) Filed: Dec. 14, 2001

(30) Foreign Application Priority Data
Dec. 14, 2000 (DE) 100 62 386.7

(51) Int. Cl. H01L 23/48; H01L 23/52; H01L 29/40

(52) U.S. Cl. 257/779

(57) ABSTRACT

An intermediate support which supports a semiconductor module on a printed circuit board has, on its underside, contact studs which are integrally formed from plastic and are intended for the contact-connection to the printed circuit board. The support is also provided with supporting studs which are preferably arranged in a comer region and are connected to the printed circuit board to improve the thermomechanical reliability of the semiconductor module.

### BACKGROUND OF THE INVENTION

The present invention is directed to an intermediate support for supporting a semiconductor module en an integrated circuit carrier, such as a printed circuit board. The intermediate support is a flat support body which is made of plastic and, on one side, has internal connections for the contact-connection to the connection element of at least one semiconductor component and, on the other side, has external connections in the form of contact studs, which are integrally formed from plastic and are connected to the internal connections via integrated conductor tracks.

The increasing miniaturization of integrated circuits gives rise to the problem of accommodating more and more electrical connections between the actual semiconductor and a circuit carrier, such as a printed circuit board, with these connections being made in an extremely confined space. The finer the structure of the semiconductor chip and of the connecting conductors, however, the more these are put at risk by different expansions of the associated materials, in particular of the semiconductor body and of the plastic printed circuit board.

A critical role in the contact-connection of semiconductor chips is played by the intermediate support or interposer, by means of which one or more chips are connected to a module which is then contact-connected to the circuit carrier or the printed circuit board.

In a so-called Ball Grid Array (BGA) technology, an intermediate support is provided over the surface area and its underside is provided with solder bumps, which allow surface mounting on a printed circuit board. The solder bumps here serve, on the one hand, as electrical connections and, on the other hand, as spacers for compensating for the expansion between the different materials, namely the intermediate support and the printed circuit board. The semiconductor chip maybe fastened on the top side of the intermediate support and contact-connected, for example, by bonding wires.

In so-called Polymer Stud Grid Array (PSGA) technology, an injection-molded, three-dimensional substrate, which is made of an electrically insulating polymer and has an underside on which polymer studs are arranged over the surface area, is used as the intermediate support. The studs of this intermediate support are preferably formed during an injection molding, as disclosed by U.S. Pat. No. 5,929,516, whose disclosure is incorporated herein by reference thereto and which claims priority from the same German Application as EP 0 782 765 and which is an example of the prior art molding. In addition to the injection molding, however, other production methods are also possible, for example the hot stamping of a plastic sheet or structuring the studs by means of lasers. The polymer studs are provided with a solderable end surface and, thus, form external connections which are connected via integrated conductor runs to the internal connections for the semiconductor component arranged on the substrate. The polymer studs serve as spacers for the module in relation to a printed circuit board and are thus capable of compensating for different expansions between the printed circuit board and the intermediate support. The semiconductor components may be contact-connected to the top side of the intermediate support via bonding wires, but is also possible, however, to be contact-connected, in the case of which the different coefficients of thermal expansion are compensated for analogously via polymer studs on the top side of the intermediate support.

U.S. Pat. No. 5,069,626, in addition, discloses a single-chip module in the case of which the injection-molded, three-dimensional substrate made of an electrically insulating polymer bears polymer studs which are integrally formed on the underside and are arranged in one or more rows along the periphery of the substrate. A chip is arranged on the top side of the substrate, and the contact-connection takes place via fine bonding wires and conductor tracks, which are then connected, for their part, via plated through-holes to the external connections formed on the studs on the underside. In this configuration, the intermediate support has a comparatively large extent.

It is generally the case that, in the case of modules with polymer studs, the thermomechanical reliability depends very much on the geometry, namely on the size of the module, the size of the semiconductor chip, the nature and number of solder connections, etc. In the case of large module dimensions and pronounced temperature fluctuations, in particular the polymer studs in the border region and in the comers, are subjected to very high stress and are put at great risk.

### SUMMARY OF THE INVENTION

The object of the present invention is for an intermediate support for a semiconductor module of the type mentioned in the introduction to be configured in a straightforward and cost-effective manner using the applied technologies so that the thermomechanical reliability is improved to a considerable extent or amount.

This object is achieved according to the invention in that the plane of the contact studs, the support body has additional supporting studs which are integrally formed from the material of the support body and are approximately at the same height as the contact studs. These supporting studs have a longitudinal extent in the direction parallel to a side of the support body which bears them, which longitudinal extent is a multiple of the diameter of one contact stud. The additional supporting studs provided according to the invention are formed in one step with the contact studs during the production of the intermediate support, with the result that virtually no additional outlay is necessary. There is no need to increase the overall thickness of the module, but it is easily possible to increase and optimize the thermomechanical reliability by means of these additional supporting studs, since it is possible for the number and configuration of these supporting studs to be selected in dependence on the geometry of the module as a whole. The supporting studs are preferably arranged as longitudinal ridges or angular ridges or in a curved form on the sides and/or comer regions of the intermediate support. Connection to the printed circuit board takes place in the same operation as that of the contact studs, that is to say usually by a reflow soldering. An adhesive bonding operation, however, is also conceivable. It is also possible for the supporting studs to perform an additional function, for example to be a contact-connection for the ground connections. The invention is explained in more detail hereinbelow by way of exemplary embodiments with reference to the drawings.

### BRIEF DESCRIPTION OF THE DRAWINGS

FIG. 1 is a partial perspective view of an intermediate support which is turned with the underside facing upward;

FIG. 2 is a partial cross-sectional view of the intermediate support of FIG. 1 supporting a semiconductor chip on a printed circuit board;

FIG. 3 is a partial plan view of the underside of the intermediate support of FIG. FIG. 4 is a partial plan view of the underside of a modification of the intermediate support of FIG. 1; and

FIG. 5 is a partial plan view of the underside of a second modification of the intermediate support of FIG. 1.

### DESCRIPTION OF THE PREFERRED EMBODIMENTS

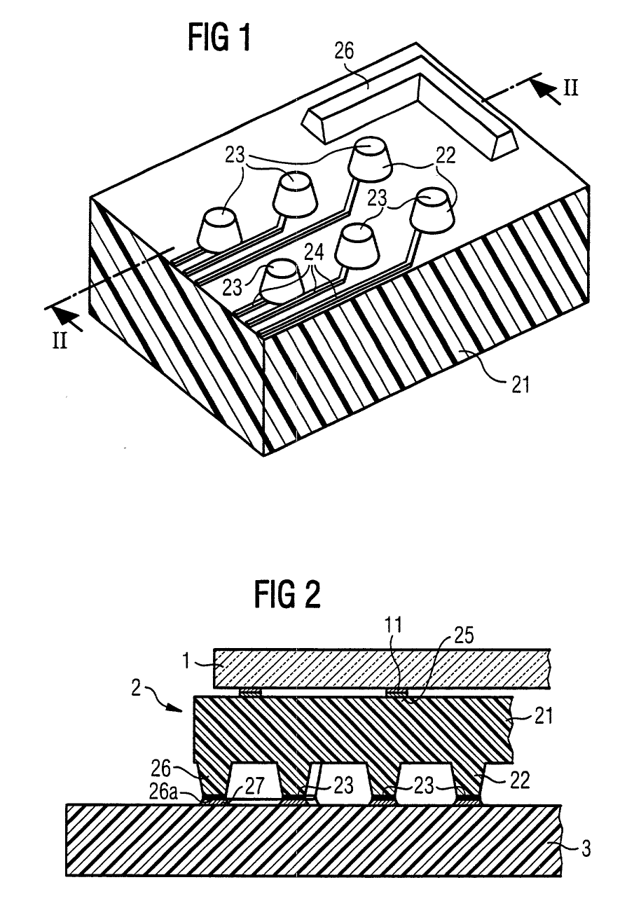

The principles of the present invention are particularly useful when incorporated in an intermediate support 2, which is illustrated in FIG. 2, for supporting a semiconductor chip 1 on a printed circuit board 3. As illustrated in FIG. 2, the intermediate support 2 comprises a flat support body 21, which is made of a thermoplastic material, which has a coefficient of thermal expansion that, as far as possible, should not differ very greatly from the coefficient of thermal expansion for the semiconductor body of the chip 1. Contact studs 22 are integrally formed in a known manner on an underside of the support body 21, and the contact studs are then distributed in a grid pattern over the surface area of the underside, as shown in FIG. 1. These contact studs are produced, for example, by an entire support body being injection molded. Another possibility, however, is a hot stamping of a sheet which may consist of a liquid crystal polymer (LCP) or some other plastic with comparable properties. A configuration by means of laser structuring is also possible. The individual contact studs are provided, at least in part, with a conductive surface for forming external contacts 23 (FIG. 1), which are connected to internal contacts 25 (FIG. 2) on the top surface via conductive connections 24, which are only schematically indicated in FIG. 1. These internal contacts, for their part, serve for the contact-connection to the contact pads 11 of the chip 1. The conductive connections between the underside and the top side of the support body 21 may be produced, for example, by conventional metallized through-passage holes, which are not shown in the drawings.

According to the invention, as shown by way of example with reference to FIGS. 1 and 2, additional supporting studs 26 are integrally formed at the corners of the support body in the same production process as the contact studs 22. The supporting studs, for example, extend as angled ridges from one corner and run parallel to the two adjacent sides of the support body 21 to form a right angle. In this example, the angle ridge 26 is located outside of the grid area of the contact stud 22 and is provided with a metallized layer 26a so that, during soldering of the module to a printed circuit board 3. The supporting studs are soldered to the printed circuit board in the same manner as the contact studs via the solder layer 27 engaging the metallized layer 26a.

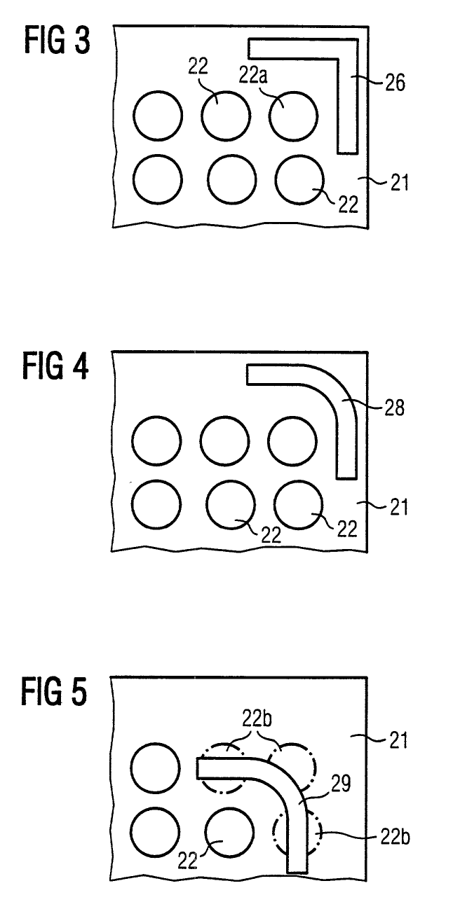

The supporting studs 26, which are preferably arranged in each case at the corners of the support body and, if required, also in the intermediate regions in addition, protect, particularly, the outer contact studs against mechanical overloading. Thus, for example, in the schematic configuration of FIG. 3, the outermost contact stud 22a is at the greatest risk, and, in this exemplary embodiment according to FIG. 3, the outer contact stud 22a is protected against overloading by the angular supporting stud 26.

Instead of the sharp angular configuration, it is also possible, however, for the supporting stud to be partially rounded, as the supporting stud 28 illustrated in FIG. 4. Further modifications in terms of both the arrangement and the shape of the stud are possible. For example, a supporting stud 29 may be included in the grid area of the contact studs and, in this case, occupy, for example, the space of three contact studs 22b, as illustrated in FIG. 5.

Although various minor modifications may be suggested by those versed in the art, it should be understood that I wish to embody within the scope of the patent granted hereon all such modifications as reasonably and properly come within the scope of my contribution to the art.

I claim:

1. An intermediate support for supporting a semiconductor module on a circuit carrier, said intermediate support having a flat support body made of a plastic and having internal connections on one side for the contact-connections of the contact elements of at least one semiconductor component and having external connections in the form of contact studs on the other side, which studs are integrally formed from plastic and are connected to the internal connections via integrated conductor tracks, said support body having additional supporting studs on the surface with the contact studs, said supporting studs being integrally formed from the material of the support body with the same height as the contact studs and with a longitudinal extent in a direction parallel to a side of the support body which supports them that is a multiple of a diameter of one contact stud.

2. An intermediate support according to claim 1, wherein the end surfaces of the supporting studs are provided with a solderable surface layer.

3. An intermediate support according to claim 2, wherein the supporting studs each run as longitudinal ridges along a side edge of the support body.

4. An intermediate support according to claim 3, wherein the supporting studs are arranged as angular ridges in the comer region of the support body.

5. An intermediate support according to claim 3, wherein the supporting studs are arranged in the form of curved ridges in the comer region of the support body.

6. An intermediate support according to claim 5, wherein the supporting studs are contact-connected as ground connections.

7. An intermediate support according to claim 4, wherein the supporting studs are contact-connected as ground connections.

8. An intermediate support according to claim 3, wherein the supporting studs are contact-connected as ground connections.

9. An intermediate support according to claim 2, wherein the supporting studs are contact-connected as ground connections.

10. An intermediate support according to claim 1, wherein the supporting studs each run as longitudinal ridges along a side of the support body.

11. An intermediate support according to claim 10, wherein the supporting studs are arranged as angular ridges in the comer region of the support body.

12. An intermediate support according to claim 10, wherein the supporting studs are arranged in the form of curved ridges in the comer regions of the support body.

13. An intermediate support according to claim 1, wherein the supporting studs are arranged as angular ridges on the support body.

14. An intermediate support according to claim 1, wherein the supporting studs are each arranged in the form of curved ridges on the support body.

15. An arrangement of a semiconductor module with an intermediate support on a circuit carrier, said intermediate supporting having a flat support body made of plastic with internal connections for contact-connection to the contact elements of the semiconductor module and at least one side having external connections in the form of contact studs, which are integrally formed from plastic and are connected to internal connections via integrated conductor tracks and are connected to the surface of the circuit carrier, said support body having additional supporting studs being integrally formed from material of the support body of the same height as the contact studs and having a longitudinal extent in the direction parallel to the side of the support body which bears them as a multiple of the diameter of the contact studs, said supporting studs being fixedly connected to the surface of the circuit carrier.

16. An arrangement according to claim 15, wherein the supporting studs are provided with a solderable surface layer and are connected to the surface of the circuit carrier by a solder.

17. An arrangement according to claim 15, wherein the supporting studs are adhesively bonded to the surface of the circuit carrier.
